(19) United States
(12) Patent Application Publication
(10) Pub. No.: US 2023/0326624 A1
(43) Pub. Date: Oct. 12, 2023

(54) OXIDE INSULATOR FILM, ELECTRONIC DEVICE AND METHOD FOR PRODUCING ELECTRONIC DEVICE

(71) Applicant: Panasonic Intellectual Property Management Co., Ltd., Osaka (JP)

(72) Inventors: Takashi SASAKI, Osaka (JP); Seiji TAGUCHI, Osaka (JP); Yoshihisa NAGASAKI, Osaka (JP); Toshiyuki TAKIZAWA, Kyoto (JP)

(21) Appl. No.: 18/043,510

(22) PCT Filed: Sep. 2, 2021
(86) PCT No.: PCT/JP2021/032356

§ 371 Date: Feb. 28, 2023

(30) Foreign Application Priority Data
Sep. 9, 2020 (JP) 2020-151625

(51) Int. Cl. H01B 3/10; H01L 29/51; H01L 21/28; H01G 4/10; H01G 4/33

(52) U.S. Cl. CPC H01B 3/10; H01L 29/517; H01L 21/28194; H01G 4/105; H01G 4/33

(57) ABSTRACT

An oxide insulator film contains a first metal oxide and a second metal oxide. An electrical conductivity of the second metal oxide is lower than an electrical conductivity of the first metal oxide. The oxide insulator film includes particles of the first metal oxide which are dispersed in a matrix including the second metal oxide.

### TECHNICAL FIELD

The present disclosure relates to oxide insulator films, electronic devices, methods for producing the electronic devices, and specifically, to an oxide insulator film containing a metal oxide, an electronic device including the oxide insulator film, and a method for producing the electronic device.

### BACKGROUND ART

Patent Literature 1 discloses a capacitor for a semiconductor device including an upper electrode, a lower electrode, and a dielectric film between the upper electrode and the lower electrode, wherein the dielectric film includes an alternately laminated film of hafnium oxide and titanium oxide at an atomic layer level. Patent Literature 1 further discloses that the dielectric film may include aluminum oxide at a predetermined percentage. Patent Literature 1 discloses that in this capacitor, increasing the thermal stability of the dielectric film and suppressing crystallization suppress cracks and pin holes from being formed due to a volume change and the like, thereby reducing a leakage current.

### CITATION LIST

### Patent Literature

Patent Literature 1: JP 2009-59889 A

### SUMMARY OF INVENTION

An oxide insulator film according to an aspect of the present disclosure contains a first metal oxide and a second metal oxide. An electrical conductivity of the second metal oxide is lower than an electrical conductivity of the first metal oxide. In the oxide insulator film, the first metal oxide is dispersed in a matrix including the second metal oxide.

An electronic device according to an aspect of the present disclosure includes a first conductor, a second conductor, and an insulator between the first conductor and the second conductor. The insulator includes the oxide insulator film.

A method for producing an electronic device according to an aspect of the present disclosure is a method for producing an electronic device including a first conductor, a second conductor, and an insulator between the first conductor and the second conductor. The insulator includes: a first metal oxide; and a second metal oxide having an electrical conductivity lower than an electrical conductivity of the first metal oxide. The method includes, to disperse the first metal oxide into a matrix including the second metal oxide, feeding each of the first metal oxide and the second metal oxide to at least one of the first conductor or the second conductor.

### BRIEF DESCRIPTION OF DRAWINGS

FIG. 1 is a sectional view of an overview of an oxide insulator film according to an embodiment of the present disclosure;

FIG. 2 is a sectional view of an example of an electronic device according to the embodiment of the present disclosure; and

FIG. 3 is a sectional view of another example of the electronic device according to the embodiment.

### DESCRIPTION OF EMBODIMENTS

### 1. Overview

First of all, an overview of an oxide insulator film and an electronic device according to the present embodiment will be described.

Conventionally, for example, in the electronic device (capacitor) of Patent Literature 1, a leak point may be formed in the dielectric film, and therefore, there is room for improvement in reducing leakage of a current (leakage current) in the dielectric film of the electronic device.

In contrast, the oxide insulator film according to the present embodiment contains a first metal oxide 1 and a second metal oxide 2. The electrical conductivity of the second metal oxide 2 is lower than the electrical conductivity of the first metal oxide 1. In the oxide insulator film 10, the first metal oxide 1 is dispersed in a matrix including the second metal oxide 2. Thus, the oxide insulator film 10 of the present embodiment can be used as an insulative material and/or an insulator in an electronic device 20. Examples of the electronic device 20 include a capacitor and a transistor. The oxide insulator film 10 can thus achieve a high dielectric constant in the electronic device 20 such as an electronic component. In the case of the oxide insulator film 10, the withstand voltage of the insulator can be suppressed from varying. This can suppress the electronic device 20 from degrading.

The reason why the oxide insulator film 10 can suppress the withstand voltage of the insulator from varying has not been exactly clarified but may be the following reasons.

Conventionally, an insulator in an electronic device is formed so as to be provided between electrode plates, and therefore, the dielectric constant of the insulator is improved by alternately stacking insulating layers formed from insulative materials having different electrical conductivities on each other. In this case, in the insulator, leak points may be formed in low-conductivity layers serving as an insulation between the electrodes, and therefore, the leak points are more likely to be electrically connected to each other via high-conductivity layers. As a result, the leak points dotting the insulator are likely to increase the variation in the withstand voltage of the insulator. In particular, when the low-conductivity layers and the high-conductivity layers are alternately stacked on each other to form the insulator, the leak points are likely to be formed. However, in the present embodiment, in an insulator film containing at least two types of metal oxides having different electrical conductivities, particles of the first metal oxide 1 having a high electrical conductivity are covered with, and enclosed in, the second metal oxide 2 which is in the form of a matrix and which has a low electrical conductivity. That is, the particles of the first metal oxide 1 are dispersed and present in the matrix including the second metal oxide 2. Thus, the second metal oxide 2 lies between the individual particles of the first metal oxide 1 having a high conductivity, which makes it difficult for the particles of the first metal oxide 1 to come into contact with each other, and consequently, both in a normal direction and in an in-plane direction in the oxide insulator film 10, insulation is achieved in fine unit of the individual particles of the first metal oxide 1, and therefore, a leak point is less likely to be formed in the insulator formed of the oxide insulator film 10. This could be considered to suppress the current leakage in the oxide insulator film 10 and can thus suppress the withstand voltage from varying.

In the present disclosure, “matrix” means that in a complex including two or more types of components, at least one type of component is covered with, and enclosed by, the other component(s). More specifically, the matrix means that the volume fraction of the other component(s) enclosing the at least one type of component is at least greater than or equal to 0.15. In the present embodiment, the matrix is formed from the component which encloses the particles of the first metal oxide 1 and which is a component other than the first metal oxide 1. Moreover, in the present embodiment, the matrix includes the second metal oxide 2.

Moreover, in the oxide insulator film 10, being a matrix can be determined by checking element distribution from a measurement result of an X-ray mapping obtained by using an Energy Dispersive X-Ray Spectrometer (EDS). Note that the determination of the matrix can be performed by checking the locations of atoms measured by a three-dimensional atom probe.

Moreover, the inventors found that the oxide insulator film 10 according to the present embodiment enables a giant dielectric constant to be exhibited. Here, the “giant dielectric constant” in the present disclosure means that a measured dielectric constant is higher than an apparent dielectric constant. Note that the “apparent dielectric constant” is a dielectric constant calculated based on equation (1) (see the description in “2. Details”). Moreover, the “measured dielectric constant” in the present disclosure can be calculated by measuring the amount of electric charges accumulated when a voltage is applied to the oxide insulator film with, for example, a dielectric constant measurement device (e.g., Precision Impedance Analyzer 4294A manufactured by Keysight Technologies). A method of measuring the dielectric constant will be described in detail in the examples described later.

Conventionally, in an insulator in multi-layer ceramic capacitors, grain boundary capacitors, and the like, the apparent dielectric constant obtainable by calculation is substantially equal to the measured dielectric constant. In contrast, the oxide insulator film 10 according to the present embodiment has a higher measured dielectric constant than an apparent dielectric constant and can exhibit the giant dielectric constant. That is, the oxide insulator film 10 can provide a dielectric constant particularly higher than that provided by the conventional insulator.

### 2. Details

Next, the oxide insulator film 10 according to the present embodiment will be described in detail. However, the embodiment described below is a mere example of various embodiments of the present disclosure. The embodiment to be described below may be readily modified in various manners depending on design without departing from the scope of the present disclosure. Note that in the following description, “A and/or B” means “A”, “B”, or “A and B”.

### Oxide Insulator Film

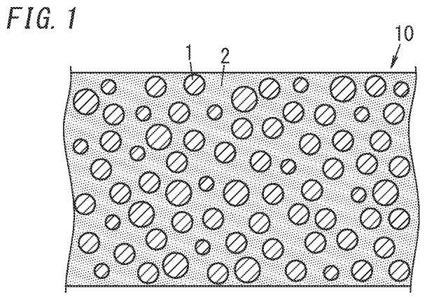

The oxide insulator film 10 of the present embodiment contains the first metal oxide 1 and the second metal oxide 2 different from the first metal oxide 1. In the oxide insulator film 10 of the present embodiment, the second metal oxide 2 encloses the first metal oxide 1 as described above, the second metal oxide 2 is used as a matrix, and particles of the first metal oxide 1 are included in the matrix including the second metal oxide. That is, into the matrix including the second metal oxide 2, the particles of the first metal oxide 1 are dispersed, thereby forming the oxide insulator film 10 (see FIG. 1). The electrical conductivity of the second metal oxide 2 is lower than the electrical conductivity of the first metal oxide 1.

The oxide insulator film 10 preferably has a measured dielectric constant higher than the apparent dielectric constant. In this case, the oxide insulator film 10 can suppress a leakage current from being caused in the oxide insulator film 10, and even in a thin film state, the oxide insulator film 10 can suppress the withstand voltage from varying.

The apparent dielectric constant is calculated based on equations (1) and (2) below. Note that in the present embodiment, the electrical conductivity of the first metal oxide 1 is satisfactorily higher than the electrical conductivity of the second metal oxide 2, and therefore, the apparent dielectric constant can be approximated by the equation (2) shown below.

γ₁=V₁/(V₁=V₂) (1)

εₐₚₚ=ε₂×(1/(1−γ₁)³) (2)

In the equation (1), V₁ is the volume of the first metal oxide 1, V₂ is the volume of the second metal oxide 2, and γ₁ is the volume fraction of the first metal oxide 1. In the equation (2), ε₂ is the relative dielectric constant of the second metal oxide 2, and εₐₚₚ is the apparent relative dielectric constant.

In the oxide insulator film 10 of the present embodiment, the measured dielectric constant is higher than the apparent dielectric constant, and therefore, the oxide insulator film 10 can exhibit the giant dielectric constant.

The film thickness (thickness) of the oxide insulator film 10 is preferably less than or equal to 100 nm. In this case, application of the oxide insulator film 10 to an insulator 11 in the electronic device 20 such as a capacitor 21 can improve the electrical capacitance of the electronic device 20. A lower limit of the film thickness of the oxide insulator film 10 is not particularly limited but may be, for example, greater than or equal to 5 nm.

Note that the “oxide” in the oxide insulator film 10 is not limited to only the metal oxide, but the “oxide” may include one or more components other than the metal oxide in combination with the metal oxide as long as the one or more components do not inhibit the effect of the present disclosure. Examples of the component other than the metal oxide include a resin component as a primer.

The dissipation factor (also referred to as dielectric loss or tans) of the oxide insulator film 10 is preferably less than or equal to 1. In this case, the insulator 11 formed of the oxide insulator film 10 can have an excellent dielectric property, thereby improving the high-frequency characteristic of the electronic device 20. The dissipation factor of the oxide insulator film 10 is more preferably less than or equal to 0.1 and much more preferably less than or equal to 0.01.

### First Metal Oxide

The first metal oxide 1 is a compound including at least one metal atom and at least one oxygen atom bonded to the metal atom. The electrical conductivity of the first metal oxide 1 is higher than the electrical conductivity of the second metal oxide 2.

The first metal oxide 1 of the present embodiment is present in particle form in the oxide insulator film 10. That is, the property of the first metal oxide 1 is preferably in particle form in the oxide insulator film 10. Note that in the present disclosure, “in particle form” means that the substance is neither in fluid form nor in dust form. Moreover, “in particle form” means that the average particle size is greater than 0.5 nm, and if the average particle size is less than or equal to 0.5 nm, this means “in dust form” or “in powder form”. The “particle form” includes a granular form. The average particle size of the first metal oxide 1 of the present disclosure can be calculated by measuring an X-ray diffraction pattern of the particles by the X Ray Diffraction (XRD) method. Specifically, the average particle size of the first metal oxide 1 can be calculated based on Scherrer equation by using a result obtained by measuring the full width half maximum of a diffraction line peak with an XRD device. Scherrer equation can be written as follows.

d=Kλ/B cos θ (3)

In equation (3), d is the average particle size, λ is the wavelength (CuKα1 0.15405 nm) of the X ray, B is the full width half maximum of the diffraction peak, θ is a Bragg angle (value which is ½ of the diffraction angle), and K is a Scherrer constant. In the present embodiment, K is 0.85.

The average particle size of the first metal oxide 1 is preferably less than or equal to 15 nm. In this case, the leak point is further suppressed from being formed in the oxide insulator film 10. Moreover, in this case, a further excellent giant dielectric constant of the oxide insulator film 10 can be exhibited. The average particle size of the first metal oxide 1 is more preferably less than or equal to 12 nm and much more preferably less than or equal to 10 nm. The lower limit of the average particle size of the first metal oxide 1 is not particularly limited but is, for example, greater than 0.5 nm.

The electrical conductivity of the first metal oxide 1 is preferably 10⁸ or more times the electrical conductivity of the second metal oxide 2. In this case, the oxide insulator film 10 can have a further increased dielectric constant, that is, the further excellent giant dielectric constant. This can impart a further excellent dielectric property to the electronic device 20 including the oxide insulator film 10. The electrical conductivity of the first metal oxide 1 is more preferably 10¹⁰ or more times, and much more preferably 10¹² or more times, the electrical conductivity of the second metal oxide 2. Note that as explained above, the electrical conductivity of the first metal oxide 1 is adjusted in accordance with the electrical conductivity of the second metal oxide 2, and the electrical conductivity of the first metal oxide 1 may be set to, for example, 10 S/m or greater. The electrical conductivity of the first metal oxide 1 is obtained by: calculating a carrier density and mobility by fitting an optical model to a result obtained by measuring a transmission absorption spectrum; and multiplying an elementary electric charge, the carrier density, and the mobility together. A method for calculating the electrical conductivity of the first metal oxide 1 will be shown in detail in the examples described later.

The first metal oxide 1 preferably contains at least one type of metal atom selected from the group consisting of Ti, V, Cr, Mn, Fe, Co, Ni, Cu, Zn, In, and Sn. That is, the first metal oxide 1 preferably contains an oxide including at least one type of metal atom selected from the group consisting of Ti, V, Cr, Mn, Fe, Co, Ni, Cu, Zn, In, and Sn. In this case, the further excellent giant dielectric constant of the oxide insulator film 10 can be exhibited. Note that in the oxide insulator film 10, the first metal oxide 1 is not limited to one type of metal oxide but may include a plurality of metal oxides as long as the effect of the present disclosure is achieved.

The average particle size of the first metal oxide 1 is preferably less than or equal to 10% of the film thickness of the oxide insulator film 10. In this case, the withstand voltage can be further suppressed from varying, the oxide insulator film 10 can have a high dielectric constant, and a further excellent giant dielectric constant can be provided. For example, when the film thickness of the oxide insulator film 10 is 100 nm, the average particle size of the particles of the first metal oxide 1 is less than or equal to 10 nm.

In the oxide insulator film 10, the volume fraction of the first metal oxide 1 is preferably greater than or equal to 0.15 and less than or equal to 0.80. In this case, the leak point is particularly suppressed from being formed in the oxide insulator film 10. Moreover, in this case, the oxide insulator film 10 can exhibit a particularly excellent giant dielectric constant. The volume fraction of the first metal oxide 1 is more preferably greater than or equal to 0.22 and less than or equal to 0.73, and much more preferably greater than or equal to 0.35 and less than or equal to 0.73. In the present embodiment, the volume fraction of the first metal oxide 1 can be calculated by being measured by a method described in the examples described later. Note that the volume fraction of the first metal oxide 1 may be the volume fraction, which is obtained by being measured with a three-dimensional atom probe, of each of composition regions.

### Second Metal Oxide

The second metal oxide 2 is a compound including at least one metal atom and at least one oxygen atom bonded to the metal atom. The electrical conductivity of the second metal oxide 2 is lower than the electrical conductivity of the first metal oxide 1.

In the present embodiment, the second metal oxide 2 serves as a matrix enclosing the particles of the first metal oxide 1 in the oxide insulator film 10.

The electrical conductivity of the second metal oxide 2 is preferably lower than or equal to 10⁻⁷ S/m. In this case, the leak point is further suppressed from being formed in the oxide insulator film 10. The electrical conductivity of the second metal oxide 2 is more preferably lower than or equal to 10⁻⁸ S/m, and much more preferably lower than or equal to 10⁻¹⁰ S/m. Note that as explained above, the electrical conductivity of the second metal oxide 2 is accordingly adjustable in accordance with the electrical conductivity of the first metal oxide 1. Regarding the electrical conductivity of the second metal oxide 2 in the oxide insulator film 10, the electrical conductivity of the oxide insulator film 10 is measured, and based on κ=κ₂/(1−γ)³ known as Hanai's approximate expression, κ₂ is calculated, and thereby, the electrical conductivity of the second metal oxide can be calculated as κ₂. Note that in the approximate expression, γ is the volume fraction of the first metal oxide 1.

The volume fraction of the second metal oxide 2 is preferably, for example, greater than or equal to 0.15. The volume fraction of the second metal oxide 2 can be measured, and calculated, by a method similar to the method used for the volume fraction of the first metal oxide 1. Note that when the oxide insulator film 10 contains only the first metal oxide 1 and the second metal oxide 2, the volume fraction of the second metal oxide 2 may be, for example, the proportion of a volume obtained by subtracting the volume fraction of the first metal oxide 1 from the entirety of the oxide insulator film 10.

The second metal oxide 2 preferably contains at least one type of metal atom selected from the group consisting of Al, Si, Ga, Zr, Nb, Hf, and Ta. That is, the second metal oxide 2 preferably contains an oxide including at least one type of metal atom selected from the group consisting of Al, Si, Ga, Zr, Nb, Hf, and Ta. In this case, the leak point is further suppressed from being formed in the oxide insulator film 10. Thus, the withstand voltage of the electronic device 20 including the oxide insulator film 10 can be further suppressed from varying. Note that in the oxide insulator film 10, the second metal oxide 2 is not limited to one type of metal oxide but may include a plurality of metal oxides as long as the effect of the present disclosure is achieved.

The second metal oxide 2 is preferably an amorphous material. In this case, the uniformity of the second metal oxide 2 can be improved, and thus the leak point is further suppressed from being formed in the oxide insulator film 10. That the second metal oxide 2 is an amorphous material is at least determined by an appropriate analysis method. For example, when a diffraction peak caused due to a crystal structure of the second metal oxide 2 is not observed by an X Ray Diffraction (XRD) method or an electron beam diffraction method, it can be determined that the second metal oxide 2 is an amorphous material.

### Method for Producing Oxide Insulator Film

The oxide insulator film 10 of the present embodiment can be produced by forming a film of a metal oxide on a base material by an appropriate method, for example, a gas phase method, a liquid phase method, or the like. Specifically, the oxide insulator film 10 may be produced by at least one type of method selected from the group consisting of, for example, a Physical Vapor Deposition (PVD) method, a Chemical Vapor Deposition (CVD) method, a sol-gel method, a hydrolysis method, and a hydrothermal synthesis method. Note that the gas phase method includes the PVD method and the CVD method. Moreover, the liquid phase method includes the sol-gel method, the hydrolysis method, and the hydrothermal synthesis method. To produce the oxide insulator film 10, forming a film by the gas phase method is preferable. In this case, the particles of the first metal oxide 1 can be satisfactorily dispersed into the matrix including the second metal oxide 2.

The PVD method and the CVD method are gas phase process and can form a film in a vapor state on a substrate. In the PVD method, for example, a raw material crystal component can be vaporized, scattered, and deposited on a substrate, thereby producing the oxide insulator film 10. In the CVD method, chemical reaction is caused in a crystal component of a raw material (also referred to as a precursor) on a substrate, thereby producing the oxide insulator film 10. Note that the PVD method is also referred to as a physical vapor deposition method, and the CVD method is also referred to as a chemical vapor deposition method.

The PVD method is, for example, at last one method selected from the group consisting of a vacuum vapor deposition method, a sputtering method, an ion plating method, a laser ablation method, and molecular beam epitaxy. The CVD method is, for example, at least one method selected from the group consisting of plasma CVD, thermal CVD, metal organic CVD (MO-CVD), atmospheric pressure CVD, low-pressure DVD, and photo CVD. The CVD method includes an Atomic Layer Deposition (ALD) method. The ALD method is a method in which two or more types of precursors are vaporized to obtain gases, and alternate introduction and discharge of the gases are repeated, and reaction of precursor molecules adsorbed on a film formation surface is caused, thereby forming a film. Note that the ALD method is also referred to as a gas introduction switching method, a gas flow modulation method, or a digital CVD method. Of these gas phase methods, the PVD method is preferable for producing the oxide insulator film 10. Moreover, the PVD method is preferably the sputtering method. When the oxide insulator film 10 is produced by the sputtering method, the particles of the first metal oxide 1 can be particularly easily enclosed in the matrix including the second metal oxide 2. Thus, the oxide insulator film 10 can have an excellent dielectric property and can particularly easily exhibit a giant dielectric constant. The sputtering method is, for example, at least one selected from the group consisting of a 2-pole sputtering method, a magnetron sputtering method, an ion beam sputtering method, and an Electron Cyclotron Resonance (ECR) sputtering method.

The sol-gel method, the hydrolysis method, and the hydrothermal synthesis method are liquid phase processes and can form a film by causing polycondensation reaction, hydrolysis, and/or crystal growth of a raw material in a liquid such as water or a dispersion medium.

A method for producing the oxide insulator film 10 by forming films of the first metal oxide 1 and the second metal oxide 2 by the sputtering method of the physical vapor deposition method will be described below with reference to specific examples.

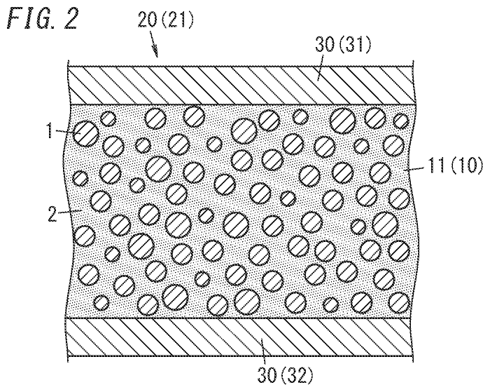

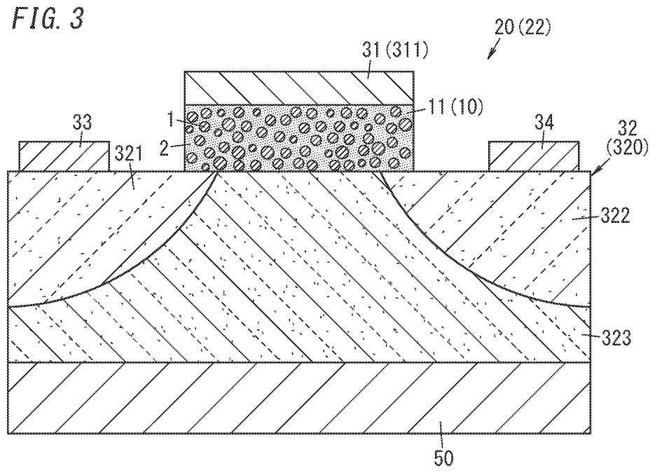

First of all, a supporting substrate 50 suitable for application of the first metal oxide 1 and the second metal oxide 2 which are raw materials is prepared. The supporting substrate 50 is not particularly limited but may include, for example, a conductor, or the supporting substrat 50 may be a conductor. Specifically, the supporting substrate 50 may be, for example, a first conductor 31 and/or a second conductor 32 as shown in FIGS. 2 and 3.

The supporting substrate 50 is disposed, for example, on an upper portion (anode side) of a sputtering device (as an example, a combinatorial sputtering device manufactured by Daiwa Kiki Kogyo Co., Ltd.) (hereinafter simply referred to also as a device), and the first metal oxide 1 and the second metal oxide 2 are disposed on a lower portion (cathode side) of the device.

Subsequently, a vacuum state is formed in the device, and then, an inert gas such as an Ar gas or the like is introduced into the device, to achieve an inert gas atmosphere. Here, the device is filled with the inert gas, and electrons are liberated in the device.

Subsequently, between the upper portion and the lower portion of the device, radio frequency RF electric power (e.g., 100 W) is input to cause collision of the inert gas filled in the device and the liberated electrons, thereby generating plasma of the inert gas. The plasma of the inert gas (ion atoms) is attracted toward the cathode side which is the lower portion provided with a raw material (in the present embodiment, the first metal oxide 1 and the second metal oxide 2) which is a target, and thereby, the plasma of the inert gas moves toward the first metal oxide 1 and the second metal oxide 2 in an accelerated manner and collides with the raw material. Thus, from a portion of the target which the ion atoms collide with, the raw material (the first metal oxide 1 and the second metal oxide 2) is vaporized, and thereby, particles of the raw material jump out and move toward the supporting substrate 50 at the anode side which is the upper portion. Then, the particles of the raw material are deposited and condensed on the supporting substrate 50, thereby forming a film. Thus, the oxide insulator film 10 can be produced on the supporting substrate 50.

The condition for the sputtering can accordingly be set based on the film thickness of the oxide insulator film 10, the average particle size of the first metal oxide 1, the volume fraction of the first metal oxide 1, and the like, and for example, the condition for the sputtering is that the chamber back pressure is 2×10⁻⁶ Pa, the film formation pressure is 0.4 Pa, the substrate temperature is a room temperature, and the oxygen partial pressure is 0.5%. Note that the condition for the sputtering is not limited to this example.

The oxide insulator film 10 of the present embodiment is produced by feeding the first metal oxide 1 and the second metal oxide 2 to an appropriate base material (e.g., the supporting substrate 50) by the gas phase method and by dispersing the particles of the first metal oxide 1 into the matrix including the second metal oxide 2.

Note that the method for producing the oxide insulator film 10 is not limited to this method, but as already explained, the oxide insulator film 10 may be produced by any appropriate method. For example, the oxide insulator film 10 may be produced by: forming the first metal oxide 1; then, adding the first metal oxide 1 to the second metal oxide 2 to obtain a mixture including the first metal oxide 1 dispersed in the second metal oxide 2; and applying the mixture to an appropriate base material (the supporting substrate 50), where the mixture may be heated if necessary. Note that the oxide insulator film 10 of the present embodiment can exhibit a particularly excellent effect when produced by the gas phase method. That is, the oxide insulator film 10 produced by the gas phase method can exhibit a particularly excellent giant dielectric constant. The reason for this is not exactly clarified but is probably that in the gas phase method, high adhesiveness between the substrate and the oxide insulator film 10 can be achieved, and in addition, the raw material can be fed with high energy compared to methods other than the gas phase method, and therefore, the temperature at the time of film formation can be reduced.

### Electronic Device and Method for Producing Electronic Device

Next, the electronic device 20 according to the present embodiment will be described in detail.

The electronic device 20 according to an aspect of the present embodiment includes a conductor 30 and the insulator 11. The conductor 30 includes the first conductor 31 and the second conductor 32. The insulator 11 lies between the first conductor 31 and the second conductor 32. The insulator 11 is the oxide insulator film 10 described above. The electronic device 20 of the present embodiment includes the oxide insulator film 10 as the insulator 11 and thus can exhibit a high dielectric property. Moreover, in the insulator 11 in the electronic device 20, the leak point is less likely to be formed, and the withstand voltage is also less likely to vary, and therefore, the insulator 11 can suppress the electronic device 20 from degrading.

The conductor 30 includes: an electrode made of, for example, metal; a transparent electrode made of indium tin oxide (ITO), aluminum zinc oxide (AZO), or the like; and a semiconductor. Both the first conductor 31 and the second conductor 32 may be conductors made of metal or the like; one of the first conductor 31 and the second conductor 32 may be a conductor, and the other of the first conductor 31 and the second conductor 32 may be a semiconductor; or both the first conductor 31 and the second conductor 32 may be semiconductors. When the conductor 30 is a semiconductor, the conductor 30 may be, for example, an N-type semiconductor or a P-type semiconductor doped with an appropriate atoms.

A method for producing the electronic device 20 of the present embodiment will be described.

The electronic device 20 of the present embodiment includes the first conductor 31, the second conductor 32, and the insulator 11 lying between the first conductor 31 and the second conductor 32 as already described. The insulator 11 contains the first metal oxide 1 and the second metal oxide 2 having a lower electrical conductivity than the first metal oxide 1. Dispersing the first metal oxide 1 into the matrix including the second metal oxide 2 includes feeding the first metal oxide 1 and the second metal oxide 2 to the conductor 30.

Note that the insulator 11 in the electronic device 20 can be produced by a method, and under conditions, similar to the method and conditions for producing the oxide insulator film 10, and therefore, redundant description thereof will accordingly be omitted.

First of all, the conductor 30 suitable for application of the first metal oxide 1 and the second metal oxide 2 which are raw materials is prepared. In the present embodiment, the conductor 30 includes the first conductor 31 and the second conductor 32.

The conductor 30 is disposed on, for example, an upper portion (anode side) of a sputtering device (hereinafter simply referred to also as a device), and in addition, the first metal oxide 1 and the second metal oxide 2 are disposed on a lower portion (cathode side) of the device.

Subsequently, a vacuum state is formed in the device, and then, an inert gas such as an Ar gas or the like is introduced into the device, to achieve an inert gas atmosphere. Here, the device is filled with the inert gas, and electrons are liberated in the device.

Subsequently, between the upper portion and the lower portion of the device, radio frequency RF electric power (e.g., 100 W) is input to cause collision of the inert gas filled in the device and the liberated electrons, thereby generating plasma of the inert gas. The plasma of the inert gas (ion atoms) is attracted toward the cathode side which is the lower portion provided with the first metal oxide 1 and the second metal oxide 2 which are targets, and thereby, the plasma of the inert gas moves toward the first metal oxide 1 and the second metal oxide 2 in an accelerated manner and collides with the raw material. Thus, from a portion of the target which the ion atoms collide with, the raw material (the first metal oxide 1 and the second metal oxide 2) is vaporized, and thereby, particles of the raw material jump out and move toward the conductor 30 at the anode side which is the upper portion. Then, the particles of the raw material (the first metal oxide 1 and the second metal oxide 2) are deposited and condensed on the conductor 30, thereby forming a film. Thus, the oxide insulator film 10 (the insulator 11) is produced on the conductor 30 (the first conductor 31 or the second conductor 32).

The condition for the sputtering can accordingly be set based on the film thickness of the oxide insulator film 10, the average particle size of the first metal oxide 1, the volume fraction of the first metal oxide 1, and the like, and for example, the condition for the sputtering is that the chamber back pressure is 2×10⁻⁶ Pa, the film formation pressure is 0.4 Pa, the substrate temperature is a room temperature, and the oxygen partial pressure is 0.5%. Note that the condition for the sputtering is not limited to this example.

On the oxide insulator film 10 formed on the first conductor 31, the second conductor 32 is superposed, thereby producing the electronic device 20.

To produce the electronic device 20, the particles of the first metal oxide 1 are dispersed into the second metal oxide 2 of at least one of the first conductor 31 or the second conductor 32. To dissipate the particles of the first metal oxide 1 into the matrix including the second metal oxide 2, each of the first metal oxide 1 and the second metal oxide 2 is preferably fed, by the gas phase method, to the conductor 30 (in the present embodiment, at least one of the first conductor 31 or the second conductor 32). In this case, the electronic device 20 in which the withstand voltage of the insulator 11 is less likely to vary is easily produced. Moreover, the insulator 11 in the electronic device 20 produced in this case can exhibit a giant dielectric constant. Also for producing the electronic device, examples of the gas phase method include the PVD method and the CVD method. The details of the PVD method and the CVD method have already been described. Among them, the gas phase method is preferably the PVD method, and the PVD method is preferably the sputtering method.

Subsequently, the electronic device 20 of the present embodiment will be described with reference to specific examples and drawings. Note that the following description is not to limit the electronic device of the present disclosure to the specific examples described below.

### Capacitor

FIG. 2 shows a capacitor 21 which is a specific example of the electronic device 20 of the present embodiment.

The capacitor 21 includes a first conductor 31, a second conductor 32, and an insulator 11. The insulator 11 lies between the first conductor 31 and the second conductor 32. The insulator 11 is the oxide insulator film 10 described above. Thus, the insulator 11 in the capacitor 21 contains the first metal oxide 1 and the second metal oxide 2.

The insulator 11 is the oxide insulator film 10 described above. The insulator 11 serves as a dielectric in the capacitor 21.

The first conductor 31 and the second conductor 32 are, for example, electrode plates of the capacitor 21. When a voltage is applied to the first conductor 31 and the second conductor 32 of the capacitor 21, the capacitor 21 can efficiently and satisfactorily accumulate electric charges because the capacitor 21 includes the oxide insulator film 10 (the insulator 11) lying between the first conductor 31 and the second conductor 32 and the insulator 11 thus has a high dielectric constant. Moreover, the capacitor 21 includes the oxide insulator film 10 as the dielectric, and thus, the capacitor 21 can suppress the withstand voltage from varying. Moreover, the capacitor 21 can have a giant dielectric constant. Thus, the capacitor 21 can have high dielectric performance (e.g., high electrical capacitance).

Note that the oxide insulator film 10 of the present embodiment may be used to produce a multi-layer capacitor.

The multi-layer capacitor is obtained, for example, by the following method.

The first metal oxide 1 and the second metal oxide 2, and optionally an appropriate resin material (e.g., a binder), are mixed with each other to obtain a mixture, which is then formed into a paste form and is formed into a sheet on a base material such as a support base material. The sheet is dried, by heating if necessary. Thus, a sheet-like dried product can be formed.

Subsequently, an internal electrode is superposed on the sheet-like dried product. The internal electrode may be printed onto the dried product by, for example, screen printing. A plurality of dried products and a plurality of internal electrodes are stacked on each other such that the dried products and the internal electrodes are alternately located, and the dried products and the internal electrodes are bonded together by compression, thereby forming a laminate. The compression bonding may be performed by, for example, an appropriate press.

The laminate is then put in a furnace, such as a heating device, a heating furnace, a baking furnace, or the like, configured to perform heating, thereby baking the laminate by heating to an appropriate temperature. By the baking, the oxide insulator film 10 is obtained from the sheet-like dried product. After the heating ends, the laminate is cooled in an appropriate manner (including leaving for cooling), and appropriate external electrodes are disposed on an outermost side of the laminate thus baked. Thus, a multi-layer capacitor including the plurality of internal electrodes, the oxide insulator film 10 (the insulator 11) lying between the plurality of internal electrodes, and external electrodes can be produced.

### Transistor

FIG. 3 shows a transistor 22 which is another specific example of the electronic device 20 of the present embodiment. Note that in FIG. 3, terminals connected to respective electrodes are omitted.

The transistor 22 includes a first conductor 31(311), a second conductor 32(320), and an insulator 11. The insulator 11 lies between the first conductor 31(311) and the second conductor 32(320). The insulator 11 is the oxide insulator film 10 described above.

The first conductor 311 is a gate electrode. The second conductor 320 is a semiconductor (or a semiconductor substrate). In FIG. 3, the semiconductor substrate is a so-called NPN semiconductor including a first n-type semiconductor 321, a p-type semiconductor 323, and a second n-type semiconductor 322 which are joined together. The first n-type semiconductor 321 and the second n-type semiconductor 322 are separated from each other by the p-type semiconductor 323. Note that the semiconductor substrate may include a supporting substrate 50. In this case, the supporting substrate 50 may be a conductor but does not have to be a conductor.

An example in which the second conductor 320 is the NPN semiconductor will be described below. Note that the second conductor 320 may be a so-called PNP semiconductor including a p-type semiconductor, an n-type semiconductor, and a p-type semiconductor which are joined in this order.

In the transistor 22, the insulator 11 is disposed on the second conductor 320 on the supporting substrate 50, and the first conductor 31(311), which is the gate electrode, is disposed on the insulator 11. In FIG. 3, the insulator 11 is in contact with all of the first n-type semiconductor 321, the p-type semiconductor 323, and the second n-type semiconductor 322 of the second conductor 320. Note that the insulator 11 may be in contact with only the p-type semiconductor 323.

In FIG. 3, the transistor 22 further includes a source electrode 33 and a drain electrode 34. The source electrode 33 is electrically connected to the first n-type semiconductor 321. The drain electrode 34 is electrically connected to the second n-type semiconductor 322. Note that in the transistor 22, the source electrode 33 may be connected to the second n-type semiconductor 322, and the drain electrode 34 may be connected to the first n-type semiconductor 321. In the transistor 22, the gate electrode 31, the source electrode 33, and the drain electrode 34 are electrically connected to each other directly or indirectly via terminals (not shown).

In the transistor 22, when a voltage is applied between the first conductor 311 (gate electrode) and the source electrode 33, electric charges (electrons and/or holes) transfer in the p-type semiconductor 323 of the second conductor 320 (the semiconductor substrate). This forms an inversion layer (not shown) at a portion which is part of the p-type semiconductor 323 and where the p-type semiconductor 323 and the insulator 11 (the oxide insulator film 10) are joined to each other. The inversion layer enables the electrons produced by application of a voltage to the transistor 22 to transfer between the first n-type semiconductor 321 and the second n-type semiconductor 322. Thus, a current can flow between the source electrode 33 and the drain electrode 34.

In the above description, a Metal-Oxide Semiconductor (MOS) transistor (Field-Effect Transistor(FET)) has been described as the electronic device 20 with reference to the example shown in FIG. 3, but the electronic device 20 may be a junction transistor. That is, the insulator 11 may be applied to a junction transistor.

When the oxide insulator film 10 of the present embodiment is included as the insulator 11 in the transistor 22, the transistor 22 can reduce the variations in the withstand voltage and can provide a high dielectric constant. The variations in the withstand voltage are reduced, and thereby, a design margin of the film thickness of the insulator 11 with respect to the withstand voltage required in the transistor 22 can be reduced, which contributes to downsizing of the transistor 22. Moreover, a high dielectric constant can be provided, and therefore, no tunneling current is produced, and even in the case of the insulator 11 having an increased film thickness, the transistor 22 can have a high electrostatic capacitance and provide a large drain current.

The electronic device 20 of the present embodiment is not limited to the above-described capacitor and transistor but may be an appropriate semiconductor element or electronic component.

### EXAMPLE

The examples of the present invention will be specifically described below. Note that the present invention is not limited to the following examples but may be modified variously depending on design as long as the object of the present invention is achieved.

### (1) Production of Oxide Insulator Film

Metal oxides including metal atoms shown in columns “Metal Type Included in Oxide 1” and “Metal Type Included in Oxide 2” in Table 1 were used to form a film by a sputtering method (co-sputtering) with a sputtering device (combinatorial) manufactured by Daiwa Kiki Kogyo Co., Ltd. on a film formed on a gold electrode disposed on a semiconductor substrate (CZ-P type manufactured by Wakatec Co., Ltd.) including silicon, thereby forming a metal oxide film. The condition for the sputtering was that the chamber back pressure was 2×10⁻⁶ Pa, the film formation pressure was 0.4 Pa, the temperature of the substrate was a room temperature (about 25° C.), the oxygen partial pressure was 0.5%, and the distance between targets was 100 mm In this way, test specimens each including an oxide insulator film having a film thickness of 100 nm were obtained.

Note that in Comparative Example 2, the sputtering condition was controlled such that the film thickness was 10 μm, thereby producing the oxide insulator film.

Components corresponding to the metal atoms shown in the columns “Metal Type Included in Oxide 1” and “Metal Type Included in Oxide 2” in Table 1 are as indicated below.

### Oxide 1

Ti: Titanium oxide (TiO₂)
Zn Zinc oxide (ZnO)
Sn: Tin oxide(SnO)
Sr: Strontium oxide (Sr₂O₃)

### Oxide 2

Al: Aluminum oxide (Al₂O₃)
Si: Silicon dioxide (SiO₂)
Zr: Zirconium oxide (ZrO)
Bi: Bismuth oxide (Bi₂O₃)

### (2) Evaluation of Oxide Insulator Film

### (2-1) Measurement of Electrical Conductivity

The electrical conductivities of the oxide 1 and the oxide 2 in the oxide insulator film of each of the examples and the comparative examples produced in (1) were measured and calculated as described below.

Specifically, for the oxide 1, a transmission absorption spectrum was measured first of all with an ultraviolet visible spectrophotometer (model number UV-2600 manufactured by Shimadzu Corporation). An obtained result of the transmission absorption spectrum was fitted to an optical model (Tauc-Lorentz model, Lorentz model, and Drude model linear combinations), thereby calculating an electron density n and an electron mobility μ. From the electron density n and the electron mobility μ thus obtained and elementary electric charge e (1.602176634×10⁻¹⁹C), the electrical conductivity of the oxide 1 was computed based on equation: Conductivity=n×e×μ. An obtained result is shown in the column “Electrical Conductivity of Oxide 1” in Table 1.

For the oxide 2, the conductivity κ of the entirety of the oxide insulator film was measured with Precision Impedance Analyzer 4294A manufactured by Keysight Technologies under the condition that the frequency was 100 Hz and the input amplitude was 5 mV. The conductivity κ of the entirety and the volume fraction (γ) calculated in (2-3) described later were obtained by calculating κ₂ in the Hanai's approximate expression. An obtained result is shown in the column “Electrical Conductivity of Oxide 2”.

### (2-2) Measurement of Average Particle Size

In the oxide insulator film of each of the examples and the comparative examples produced in (1), the X-ray diffraction pattern of the particles of the oxide 1 was measured with an X-ray diffraction device (automatic X-ray diffraction device model number RINT2100 manufactured by Rigaku Corporation) under the condition that the measurement wavelength was 0.15405 nm (CuKα ray), 2θ=25 to 40°, the interval was 0.05°, and the integrated time was 0.5 seconds. From a measurement result of the full width half maximum of the diffraction line peak thus obtained, the average particle size of the oxide 1 was calculated based on Scherrer equation shown below.

d=Kλ/B cos θ

In the equation, d is the average particle size, λ is the wavelength of an X ray, B is the full width half maximum of the diffraction peak, θ is a diffraction angle, and K is Scherrer constant, where K is 0.85. The result is shown in the column “Average Particle Size of Oxide 1” in Table 1.

### (2-3) Calculation of Volume Fraction

The volume fraction of the oxide insulator film of each of the examples and the comparative examples produced in (1) was measured and calculated as described below. First of all, an average composition of the entirety of the oxide insulator film was obtained with an X-ray photoelectron spectrometer (model number ESCA-3400HSE manufactured by Shimadzu Corporation), and based on phases preset in the average composition in a phase diagram, the ratio of the oxides 1 and 2 to the oxide insulator film in terms of substance quantity of the phases was calculated. Note that to calculate the ratio in terms of the substance quantity, only metal elements are taken into consideration. Subsequently, the volume fraction of each phase was calculated based on the volume per substance quantity obtained from the molecular weight of a corresponding one of the phases and the volume per chemical formula (composition formula). The result is shown in the column “Volume Fraction of Oxide 1” in Table 1.

### (3) Production of Electronic Device

On each test specimen including the silicon substrate produced in (1), a gold electrode (lower electrode), and an oxide insulator film, a gold electrode (upper electrode) is further disposed on an opposite surface of the oxide insulator film from the lower electrode, thereby producing an electronic device.

### (4) Evaluation of Electronic Device

(4-1) Calculation of Apparent Dielectric Constant (Relative Dielectric Constant) The apparent dielectric constant of the electronic device of each of the examples and the comparative examples produced in (3) was calculated based on equations (1) and (2) described below. Note that the electrical conductivity of the oxide 1 is satisfactorily higher than the electrical conductivity of the oxide 2, and therefore, in the apparent dielectric constant can be approximated by the equation (2) shown below.

γ₁=V₁/(V₁+V₂) (1)

εₐₚₚ=ε₂×(1/(1−γ₁)³) (2)

In the equation (1), Vi is the volume of the oxide 1, V₂ is the volume of the oxide 2, and γ₁ is the volume fraction of the oxide 1. In the equation (2), ε₂ is the relative dielectric constant of the oxide 2, and εₐₚₚ is the apparent relative dielectric constant. The result is shown in the column “Apparent Dielectric Constant (Calculation Value)” in Table 1.

### (4-2) Measurement of Dielectric Constant (Relative Dielectric Constant)

For the electronic device of each of the examples and the comparative examples produced in (3), the relative dielectric constant was measured with a dielectric constant measurement device (model number Precision Impedance Analyzer 4294A manufactured by Keysight Technologies) under the condition of the room temperature (about 25° C.) and a frequency of 100 Hz. The result is shown in the column “Dielectric Constant (Measured @10² Hz)” in Table 1.

### (4-3) Measurement of Withstand Voltage and Calculation of Variation in Withstand Voltage

In the electronic device of each of the examples and the comparative examples produced in (3), the current density during voltage sweep was measured with Semiconductor Parameter Analyzer 4155C manufactured by Keysight Technologies under the condition that the sweep start voltage was 0 V, the sweep interval was 0.05 V, integral time was 0.1 seconds, and the compliance current was 10 μA. At least three values were obtained on a lower voltage side of a voltage step whose increase rate of current density is greater than 3 decade/step, and an average value of these values and unbiased standard deviation were calculated. Here, the average value of the voltage is the withstand voltage, and the unbiased standard deviation is the variation in the withstand voltage. The result is shown in columns “Withstand Voltage” and “Variation in Withstand Voltage” in Table 1.

### (4-4) Dielectric Loss (Tan δ)

In the electronic device of each of the examples and the comparative examples produced in (3), a dielectric loss (tan δ) was measured with a measurement device similar to that in (4-2) under the condition of room temperature (about 25° C.) and a frequency of 100 Hz. The result is shown in the column “Dielectric Loss tans (Measured @10² Hz)” in Table 1.

TABLE 1

| | | | | | | | Average | Apparent | | | |
|---|---|---|---|---|---|---|---|---|---|---|---|
| | | Metal | Metal | Electrical | Electrical | Volume | Particle | Dielectric | Dielectric | | Variation in |
| | | Type | Type | Conductivity | Conductivity | Fraction | Size of | Constant | Constant | Withstand | Withstand |
| | | Included | Included | of Oxide 1 | of Oxide 2 | of Oxide 1 | Oxide 1 | (Calculated | (Measured | Voltage | Voltage |
| | | in Oxide 1 | in Oxide 2 | [S/m] | [S/m] | [vol %] | [nm] | Value) | @10² Hz) | [V] | [%] |
| Examples | 1 | Ti | Al | 8 × 10⁴ | 5 × 10⁻¹¹ | 0.42 | 3 | 51 | 653 | 15 | 2 |
| | 2 | Ti | Si | 9 × 10² | 2 × 10⁻¹² | 0.53 | 7 | 34 | 832 | 11 | 4 |
| | 3 | Ti | Zr | 1 × 10⁴ | 4 × 10⁻⁹ | 0.40 | 4 | 162 | 524 | 9 | 2 |
| | 4 | Zn | Zn, Al | 4 × 10¹ | 4 × 10⁻⁸ | 0.22 | 9 | 21 | 378 | 24 | 5 |
| | 5 | Zn | Zn, Si | 2 × 10³ | 1 × 10⁻⁸ | 0.35 | 2 | 13 | 216 | 9 | 1 |
| | 6 | Zn | Zr | 7 × 10² | 1 × 10⁻⁹ | 0.42 | 5 | 179 | 714 | 8 | 5 |
| | 7 | Sn | Si | 3 × 10⁶ | 6 × 10⁻¹² | 0.73 | 6 | 178 | 392 | 2 | 2 |
| | 8 | Sn | Al | 2 × 10¹ | 3 × 10⁻¹¹ | 0.37 | 8 | 40 | 788 | 19 | 3 |
| | 9 | Sn | Zr | 6 × 10² | 8 × 10⁻⁸ | 0.57 | 8 | 440 | 641 | 3 | 3 |
| | 10 | Zn | Zn, Si | 5 × 10³ | 1 × 10⁻⁸ | 0.35 | 12 | 13 | 43 | 9 | 13 |
| | 11 | Sn | Zr | 3 × 10² | 4 × 10⁻⁸ | 0.15 | 3 | 57 | 65 | 25 | 15 |
| | 12 | Sn | Zr | 1 × 10³ | 8 × 10⁻⁹ | 0.80 | 10 | 1250 | 1423 | 0.3 | 24 |
| | 13 | Zn | Zn, Si | 6 × 10⁴ | 3 × 10⁻⁷ | 0.35 | 2 | 13 | 197 | 9 | 1 |
| | 14 | Zn | Zn, Si | 2 × 10¹ | 7 × 10⁻⁷ | 0.35 | 7 | 13 | 59 | 8 | 1 |
| Comparative | 1 | Ti | Si | 4 × 10² | 6 × 10⁻⁶ | 0.88 | 34 | 2025 | 2004 | 0.2 | 62 |
| Examples | 2 | Sr, Ti | Sr, Ti, Bi | 1 × 10⁻¹ | 3 × 10⁻⁴ | 0.91 | to 5,000 | 3.4 × 10⁵ | 2.8 × 10⁵ | 1 | 51 |

In each of Examples 1 to 14, the variation in the withstand voltage is less than or equal to 25%. In particular, in Examples 1 to 9, 13, and 14, the variation was suppressed to be lower than or equal to 5%. In contrast, in Comparative Examples 1 and 2, the variation in the withstand voltage is greater than 50%. This is probably because in Examples 1 to 14, the electrical conductivity of the oxide 1 is lower than the electrical conductivity of the oxide 2, and the particles of the oxide 1 are in the matrix of the oxide 2 and are covered with the oxide 2.

Moreover, Examples 1 to 14 suggest that these examples exhibit the giant dielectric constant, and in particular, that Examples 1, 2, 4, 5, 8, and 13 can provide a dielectric constant which is 10 or more times the apparent dielectric constant (relative dielectric constant). In contrast, the comparative examples show that the measured dielectric constant (relative dielectric constant) is lower than the apparent dielectric constant (relative dielectric constant) and that the giant dielectric constant cannot be provided.

Moreover, Examples 1 to 14 show that the dielectric loss can be low compared to Comparative Examples 1 and 2, and it was found that a high high-frequency characteristic can be provided. In particular, Examples 1 to 12 suggest that the dielectric loss can be reduced as low as 0 and that a further excellent high-frequency characteristic can be provided.

### 3. Summary

As can be seen from the embodiment and examples described above, the present disclosure includes the following aspects. In the following description, reference signs in parentheses are shown only to clarify the correspondence relationship to the embodiment.

An oxide insulator film (10) of a first aspect contains a first metal oxide (1) and a second metal oxide (2), an electrical conductivity of the second metal oxide (2) being lower than an electrical conductivity of the first metal oxide (1), the first metal oxide (1) being dispersed in a matrix including the second metal oxide (2).

The first aspect enables the oxide insulator film (10) to be used as an insulative material and/or an insulator in an electronic device (20) and a high dielectric constant to be provided in the electronic device (20). Moreover, this aspect enables, in the oxide insulator film (10), the withstand voltage of the insulator to be suppressed from varying. This enables the electronic device (20) to be suppressed from degrading.

In an oxide insulator film (10) of a second aspect referring to the first aspect, a measured dielectric constant of the oxide insulator film (10) is higher than an apparent dielectric constant of the oxide insulator film (10). The apparent dielectric constant is calculated based on equation (1) and equation (2) below.

γ₁=V₁/(V₁+V₂) (1)

εₐₚₚ=ε₂×(1/(1−γ₁)³) (2)

In the equation (1), Vi is a volume of the first metal oxide (1), V₂is a volume of the second metal oxide (2), and γ₁ is a volume fraction of the first metal oxide (1). In the equation (2), γ₂ is a dielectric constant of the second metal oxide (2), and εₐₚₚ is an apparent dielectric constant.

According to the second aspect, the measured dielectric constant is higher than the apparent dielectric constant, which therefore enables a giant dielectric constant to be exhibited.

An oxide insulator film (10) of a third aspect referring to the first or second aspect, the first metal oxide (1) has an average particle size of less than or equal to 10% of a film thickness of the oxide insulator film (10).

The third aspect enables the withstand voltage of the oxide insulator film (10) to be further suppressed from varying, the oxide insulator film (10) to have a high dielectric constant, and a further excellent giant dielectric constant to be provided.

An oxide insulator film (10) of a fourth aspect referring to any one of the first to third aspects, the oxide insulator film (10) has a thickness of 100 nm or less.

According to the fourth aspect, applying the oxide insulator film (10) to the insulator (11) in the electronic device (20) enables the electrical capacitance of the electronic device (20) to be further enhanced.

An oxide insulator film (10) of a fifth aspect referring to any one of the first to fourth aspects, the first metal oxide (1) has an average particle size of less than or equal to 15 nm.

The fifth aspect enables a leak point to be further suppressed from being formed in the oxide insulator film (10). This aspect also enables a further excellent giant dielectric constant of the oxide insulator film (10) to be exhibited.

In an oxide insulator film (10) of a sixth aspect referring to any one of the first to fifth aspects, the first metal oxide (1) has a volume fraction of greater than or equal to 0.15 and less than or equal to 0.80.

The sixth aspect enables a leak point to be particularly suppressed from being formed in the oxide insulator film (10). This aspect also enables a particularly excellent giant dielectric constant of the oxide insulator film (10) to be exhibited.

In an oxide insulator film (10) of a seventh aspect referring to any one of the first to sixth aspects, the electrical conductivity of the second metal oxide (2) is less than or equal to 10⁻⁷ S/m.

The seventh aspect enables a leak point to be further suppressed from being formed in the oxide insulator film (10).

In an oxide insulator film (10) of an eighth aspect referring to any one of the first to seventh aspects, the electrical conductivity of the first metal oxide (1) is 10⁸ or more times the electrical conductivity of the second metal oxide (2).

The eighth aspect enables a further excellent giant dielectric constant of the oxide insulator film (10) to be exhibited.

In an oxide insulator film (10) of a ninth aspect referring to any one of the first to eighth aspects, the first metal oxide (1) contains at least one type of metal atom selected from the group consisting of Ti, V, Cr, Mn, Fe, Co, Ni, Cu, Zn, In, and Sn.

The ninth aspect enables a further excellent giant dielectric constant of the oxide insulator film (10) to be exhibited.

In an oxide insulator film (10) of a tenth aspect referring to any one of the first to ninth aspects, the second metal oxide (2) contains at least one type of metal atom selected from the group consisting of Al, Si, Ga, Zr, Nb, Hf, and Ta.

The tenth aspect enables a leak point to be further suppressed from being formed in the oxide insulator film (10).

In an oxide insulator film (10) of an eleventh aspect referring to any one of the first to tenth aspects, the first metal oxide (1) and the second metal oxide (2) are fed by a gas phase method such that particles of the first metal oxide (1) are dispersed into the matrix including the second metal oxide (2).

The eleventh aspect enables the oxide insulator film (10) as an insulator in the electronic device (20) to have a high dielectric constant and the withstand voltage of the insulator to be further suppressed from varying.

An electronic device (20) of a twelfth aspect includes a first conductor (31), a second conductor (32), and an insulator (11) between the first conductor (31) and the second conductor (32). The insulator (11) is the oxide insulator film (10) of any one of the first to eleventh aspects.

According to the twelfth aspect, the electronic device (20) includes the oxide insulator film (10) as the insulator (11), which therefore enables a high dielectric property to be exhibited. Moreover, in the insulator (11) in the electronic device (20), the leak point is less likely to be formed, and the withstand voltage is also less likely to vary, and therefore, the insulator (11) enables the electronic device (20) to be suppressed from degrading.

A method for producing an electronic device (20) of a thirteenth aspect is a method for producing an electronic device including a first conductor (31), a second conductor (32), and an insulator (11) between the first conductor (31) and the second conductor (32). The insulator (11) contains a first metal oxide (1) and a second metal oxide (2) different from the first metal oxide (1). The method includes, to dissipate the first metal oxide (1) into a matrix including the second metal oxide (2), feeding the first metal oxide (1) and the second metal oxide (2) to at least one of the first conductor (31) or the second conductor (32).

The thirteenth aspect enables the electronic device (20) which suppresses the withstand voltage of the insulator (11) from varying and provides a giant dielectric constant to be formed.

In a method for producing the electronic device (20) of a fourteenth aspect referring to the thirteenth aspect, each of the first metal oxide (1) and the second metal oxide (2) is fed to at least one of the first conductor (31) or the second conductor (32) by a gas phase method.

According to the fourteenth aspect, the electronic device (20) which suppresses the withstand voltage of the insulator (11) from varying and which provides a giant dielectric constant is easily formed.

### REFERENCE SIGNS LIST

1 First Metal Oxide (Particle)
2 Second Metal Oxide
10 Oxide Insulator Film
11 Insulator
20 Electronic Device
30 Conductor
31 First Conductor
32 Second Conductor
311 First Conductor (Gate Electrode)
320 Second Conductor (Semiconductor Substrate)

1. An oxide insulator film comprising:
a first metal oxide; and
a second metal oxide, an electrical conductivity of the second metal oxide being lower than an electrical conductivity of the first metal oxide,
the first metal oxide being dispersed in a matrix including the second metal oxide.

2. The oxide insulator film of claim 1, wherein
a measured dielectric constant of the oxide insulator film is higher than an apparent dielectric constant of the oxide insulator film, and
the apparent dielectric constant is calculated based on equation (1) and equation (2)
γ₁=V₁/(V₁+V₂) (1)
εₐₚₚ=×(1/(1−γ₁)³) (2)
where, in the equation (1), Vi is a volume of the first metal oxide, V₂ is a volume of the second metal oxide, and γ₁ is a volume fraction of the first metal oxide, and in the equation (2), ε₂ is a dielectric constant, and εₐₚₚ is an apparent dielectric constant of the second metal oxide.

3. The oxide insulator film of claim 1, wherein
the first metal oxide has an average particle size of less than or equal to 10% of a film thickness of the oxide insulator film.

4. The oxide insulator film of claim 1, wherein
the oxide insulator film has a thickness of 100 nm or less.

5. The oxide insulator film of claim 1, wherein
the first metal oxide has an average particle size of less than or equal to 15 nm.

6. The oxide insulator film of claim 1, wherein
the first metal oxide has a volume fraction of greater than or equal to 0.15 and less than or equal to 0.80.

7. The oxide insulator film of claim 1, wherein
the electrical conductivity of the second metal oxide is less than or equal to 10⁻⁷ S/m.

8. The oxide insulator film of claim 1, wherein
the electrical conductivity of the first metal oxide is 10⁸ or more times the electrical conductivity of the second metal oxide.

9. The oxide insulator film of claim 1, wherein
the first metal oxide contains at least one type of metal atom selected from the group consisting of Ti, V, Cr, Mn, Fe, Co, Ni, Cu, Zn, In, and Sn.

10. The oxide insulator film of claim 1, wherein
the second metal oxide contains at least one type of metal atom selected from the group consisting of Al, Si, Ga, Zr, Nb, Hf, and Ta.

11. The oxide insulator film of claim 1, wherein
the first metal oxide and the second metal oxide are fed by a gas phase method such that particles of the first metal oxide are dispersed into the matrix including the second metal oxide.

12. An electronic device comprising:
a first conductor;
a second conductor; and
an insulator between the first conductor and the second conductor,
the insulator being the oxide insulator film of claim 1.

13. A method for producing an electronic device including a first conductor, a second conductor, and an insulator between the first conductor and the second conductor, the insulator containing a first metal oxide and a second metal oxide having an electrical conductivity lower than an electrical conductivity of the first metal oxide,
the method comprising, to dissipate the first metal oxide into a matrix including the second metal oxide, feeding each of the first metal oxide and the second metal oxide to at least one of the first conductor or the second conductor.

14. The method of claim 13, wherein
each of the first metal oxide and the second metal oxide is fed to at least one of the first conductor or the second conductor by a gas phase method.
